(19) United States
(12) Patent Application Publication
(10) Pub. No.: US 2001/0005408 A1
(43) Pub. Date: Jun. 28, 2001

(54) Electronic device with a frequency synthesis circuit

(76) Inventor: Simon Markus Neukom, Uster (CH)

Correspondence Address: Jack E. Haken, c/o U.S. PHILIPS CORPORATION, Intellectual Property Department, 580 White Plains Road, Tarrytown, NY, 10591, US

(21) Appl. No.: 09/734,074

(22) Filed: Dec. 11, 2000

(30) Foreign Application Priority Data
Dec. 15, 1999 (EP) 99204327.3

(51) Int. Cl. H03L 7/06; H03D 3/24

(52) U.S. Cl. 375/376; 327/156

(57) ABSTRACT

An electronic circuit contains a phase locked loop. The phase of a frequency divided output signal of a controllable oscillator is compared with the phase of a reference signal and the result of the phase comparison is used to control the frequency of the controllable oscillator. Frequency division is by time-varying integer division ratios, so that the integer division ratios on average substantially equal a nominal division ratio. The loop contains a variable delay circuit coupled between the controllable oscillator and the input of the frequency divider. Delays of the delay circuit are controlled so that the delays prevent deviations between period lengths of the output signal of the divider. The period lengths are made equal to period lengths of a notional signal with a frequency equal to the frequency of the oscillator divided by the nominal division ratio.

### BACKGROUND ART

Frequency synthesis is discussed in an article by V. Reinhardt, K. Gould, K. McNab, M. Bustamante, titled “A short survey of frequency synthesizer techniques” and published in the proceedings of the 40^{th} Annual frequency control symposium 1986 (pages 355 to 365). Reinhardt et al. mention a technique called “Phase Interpolation DDS” (DDS= Digital Direct Synthesis). As shown, this technique involves a Phase Locked Loop, in which a frequency divided output of a VCO 10 is compared with a reference signal in a phase detector. The output of the phase detector is used to control the oscillation frequency of the VCO 10.

In order to realize a non-integer ratio between the frequencies of the VCO 10 and the reference signal, the frequency division ratio is varied in time (or, equivalently, some of the output pulses of the VCO 10 are “swallowed” and not applied to the frequency divider), so that the average a the division ratio equals the desired non-integer ratio. Furthermore, a correction is added to the output of the phase detector before this output is applied to the VCO 10. The correction serves to compensate time dependent jitter that is due to the variations of the division ratio.

This circuit is based on a computation of the phase error due to the integer division ratio of the frequency divider. The phase error is the difference between the phase of the “ideal” divided signal (divided by the non-integer ratio) and the actual divided signal (divided with the integer ratio). Reinhart et al. compute the phase error and use it to generate the correction. If the error grows too large, the division ratio is temporarily stepped up, which makes the phase error decrease.

For a high precision correction this circuit requires a highly linear phase detector and an accurate phase error to correction voltage converter.

In U.S. Pat. No. 5,459,766 another frequency synthesis technique is shown. Here, the phase of a controlled oscillator is measured digitally and compared to a desired phase, which is computed digitally for time points determined by a reference oscillator.

### SUMMARY OF THE INVENTION

Amongst others, it is an object of the invention to provide a device with a frequency synthesizer in which jitter is reduced without an accurate linear phase detector or high precision phase to voltage conversion.

The device according to the invention is set forth in claim 1. According to the invention the output signal of a frequency controlled oscillator is delayed by an adjustable amount before it is frequency divided and used in a loop to control the frequency of the oscillator.

Preferably, the output signal of the frequency controlled oscillator is delayed by means of a delay locked loop, which adjusts the delay to a rational fraction (a ratio of two integers) of the period of the signal from the controlled oscillator. It has been found that jitter can be removed completely in this way if a rational ratio is desired between the frequency of the controlled oscillator and the frequency of the reference signal.

In an embodiment, the delay is adjusted in steps to ensure that adjustment of the delay does not cause additional pulses to be supplied to the frequency divider.

These and other advantageous aspects of the invention will be described in more detail using the following figures.

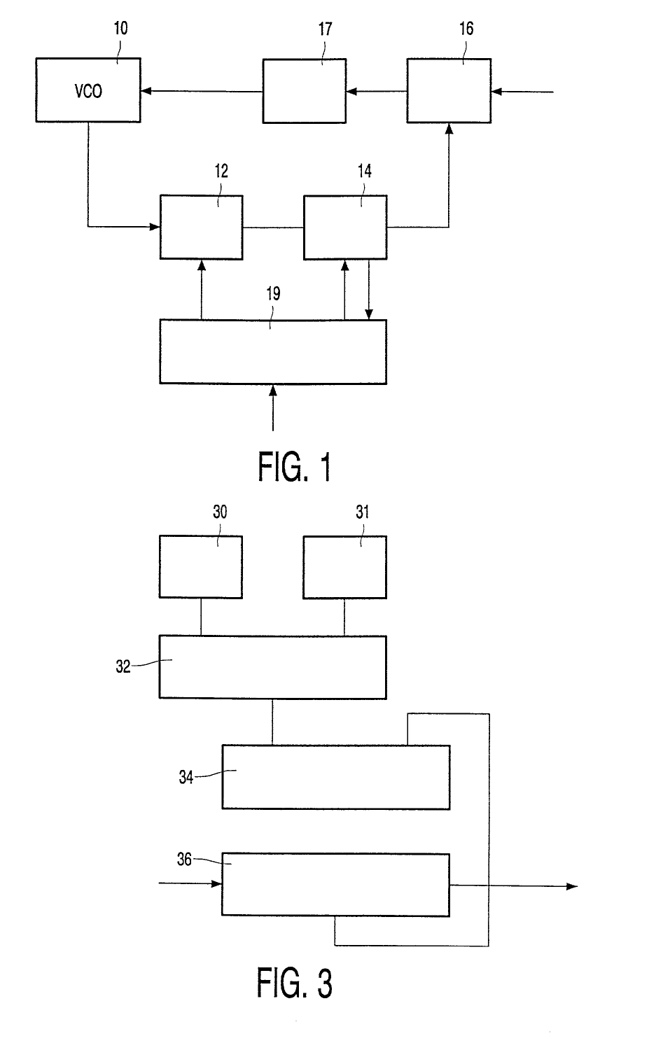

FIG. 1 shows a frequency synthesizer circuit,

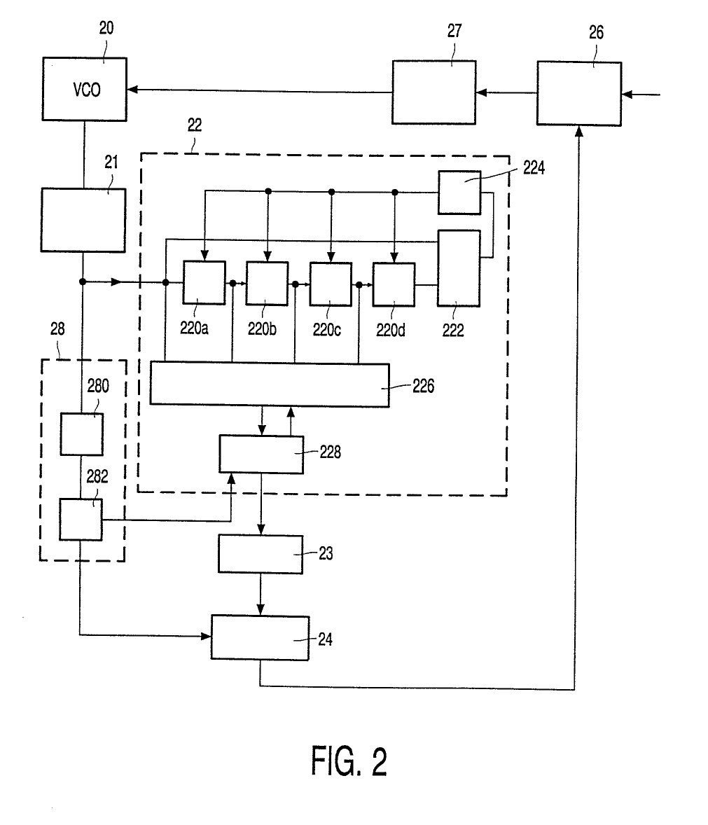

FIG. 2 shows a further frequency synthesizer circuit,

FIG. 3 shows a frequency divider circuit.

FIG. 1 shows a frequency synthesizer circuit. The circuit comprises a VCO 10, a delay circuit 12, a frequency divider 14, a phase detector 16, a loop filter 17 and a control circuit 19. The VCO 10 has an output coupled to the frequency divider 14 via the delay circuit 12. The phase detector 16 has two inputs, one coupled to an output of the frequency divider 14 another coupled to an input for a reference signal. The phase detector 16 has an output that controls the frequency of the VCO 10 via the loop filter 17. The control circuit 19 has a control output coupled to the delay circuit 12 and a control input and output coupled to the frequency divider 14. The control circuit 19 has an input for receiving information that indicates a desired ratio between the frequency of the output signal of the VCO 10 and the reference signal.

In operation, the circuit of FIG. 1 locks the phase of a frequency divided and phase corrected output signal of the VCO 10 to the reference signal. The delay circuit 12 delays the output signal of the VCO 10. The frequency divider 14 frequency divides the delayed output signal of the VCO 10. The phase detector 16 compares the phase of the delayed and frequency divided output signal of the VCO 10 with the phase of the reference signal. The output of the phase detector 16 controls the VCO via the loop filter 17, so that the difference between the phase of the delayed and frequency divided output signal of the VCO 10 with the phase of the reference signal is regulated to a fixed value.

The control circuit 19 controls the division ratio N of the frequency divider 14 and the delay D of the delay circuit 12. The control circuit 19 does so to promote a desired ratio X between the frequency of the output signal of the VCO 10 and the frequency F of the reference signal. The choice of N and D is based on the following considerations.

The phase of the delayed and frequency divided output signal of the VCO 10 is compared with the phase of the reference signal at timepoints 1/F apart. When the output signal of the VCO 10 should have a frequency XF, N periods of this output signal should take a time interval N/XF. The change CD in the delay D during the N periods should make up for the difference between 1/F and N/XF:

CD=(X−N)/XF

That is, CD equals X-N periods of the output signal of the VCO 10. When the control circuit 19 changes the delay D by this amount every time between the start of counting N periods by the frequency divider 14 and the completion of that counting the phase detector 16 and the loop filter 17 will ensure that the frequency of the VCO 10 is regulated towards the desired frequency XF. Of course, a non-zero change CD would cause the required delay to increase indefinitely, which would not be realizable with a practical delay circuit 12. To prevent this, the control circuit 19 now and then changes the value of N so as to change the sign of CD (taking N above and below X) so that the value of D remains within a range that can be realized with the delay circuit. This can be realized for example by normally taking N equal to the next integer below X and changing N to the next integer above X every time when the next CD would require a change the delay D outside the operating range of delay circuit 22.

The control circuit 19 does not need to change the delay D all at once: the delay D may be changed gradually, as long as the change is complete before the Nth pulse of the output signal of the VCO 10 reaches the frequency divider 14.

FIG. 2 shows a further frequency divider circuit. The circuit comprises a VCO 20, a prescaler 21, a delay circuit 22, a further delay circuit 23, a frequency divider 24, a phase detector 26, a loop filter 27 and a control circuit 29. The VCO 20 has an output coupled to the frequency divider 24 via successively the prescaler 21, the delay circuit 22 and the further delay circuit 23. The phase detector 26 has two inputs, one coupled to an output of the frequency divider 24, another coupled to an input for a reference signal. The phase detector 26 has an output that controls the frequency of the VCO 20 via the loop filter 27.

The delay circuit 22 contains a delay locked loop, comprising a number of identical controllable delay stages 220a-d in cascade, a further phase detector 222, a further loop filter 224, a multiplexer 226 and an address controller 228. An input of the delayed delay circuit is coupled to an initial one of the controllable delay stages 220a and to a first input of the further phase detector 222. An output of a final one of the controllable delay stages 220d is coupled to a second input of the further phase detector 222. An output of the further phase detector 222 is coupled to control inputs of the controllable delay stages 220a-d via loop filter 224. The inputs of the controllable delay stages 220a-d are coupled to inputs of the multiplexer 226. The address controller 228 is coupled to the output of the multiplexer 226 and to a control input of the multiplexer 226. An output of the address controller 228 forms an output of the delay circuit 22.

The control circuit 29 has a control core 282 with a control output coupled to address controller 228 and a control output coupled to the frequency divider 24. The control core 282 has an input for receiving information that indicates a desired ratio between the frequency of the output signal of the VCO 20 and the reference signal. The control circuit 29 contains a further divider 280, which has an input coupled to the input of the delay circuit 22 and an output coupled to the control core 282.

In operation, the circuit of FIG. 2 works similar to the circuit of FIG. 1. The prescaler 21 performs a frequency predivision of the output signal of the VCO 20. This is not essential for the invention: it merely reduces the maximum frequency used in the remainder of the circuit.

The delay locked loop in the delay circuit 22 regulates the delay of the controllable delay stages 220a-b. Each delay stage 220a-d has the same delay, which is regulated by the phase detector so that the sum of these delays stands in a fixed ratio (e.g. 1) to the period of the input signal: with M delay stages 220a-d (M=4 in FIG. 2, but a larger or smaller number of delay stages may be used in cascade), each delay stage 220a-d may delay the signal from the prescaler 21 by 1/M period T of that signal. The address controller 228 selects a desired delay (of a fraction K/M of a period) and causes the multiplexer 226 to pass a signal that has gone through K stages (K from 0 to M−1), and therefore has a delay of TK/M under control of the control core 282.

Of course more complex types of delay circuit may also be used. For example, one may use a cascade of delay locked loops, each with a different resolution, so that the total delay can be adjusted more finely. As another example, a first multiplexer may be used that has two outputs that can be connected to an input and an output of the same selectable delay stage 220a-d from the cascade (called first cascade in this example). These outputs are then connected to another phase detector, the most delayed output directly, the least delayed via a second cascade of adjustable delay stages, the delay of this second cascade being controlled by the other phase detector to make its delay equal to the delay of the delay stage to which the outputs of the multiplexer are connected. The inputs of the delay stages of this second cascade are coupled to a second multiplexer. Thus, the first multiplexer may be used for a coarse delay selection and the second multiplexer for a fme selection. Additional delay locked loops of this type and multiplexers may be cascaded in this way to provide even finer selection.

Further divider 280 signals to the control core 282 when N periods of the output signal of the prescaler 21 have passed. Control core 282 computes the required delay D for the next N periods as described for FIG. 1 and signals that required delay to address controller 228. Further divider 280 has been provided in addition to divider 24. Further divider 280 receives the signal from prescaler 21 with less delay than divider 24, because its input signal does not pass through delay circuit 22 and further delay circuit 23. Thus, further divider 280 signals completion of a period of the divided signal to control core 282 before the normal divider 24 completes the period of its divided signal. This enables control core 282 to compute the frequency division ratio and delay before completion of the period of normal divider, which allows a rapid adjustment of the delay, directly after completion of the period. Consequently delays can be adjusted before completion of the next period of the divided signal even if the division ratio is very small. The delay of further delay circuit 24 may be designed to ensure that control core 282 always has sufficient time. Of course further divider 280 and further delay circuit 23 may be omitted if no extra time is required for control core 282.

The address controller 228 has to ensure that the changes in the delay do not cause the delay circuit 22 to generate additional pulses. This means that both the signal selected by the multiplexer 226 before and after the change in delay should output the same pulse, be it with a different delay. To realize this, selection changes of the multiplexer 226 is clocked by transitions at the output of the multiplexer 226. If selection changes to an “earlier” output of the multiplexer 226 (i.e. an output which outputs a signal that is less delayed than the signal of the previously selected output), the change should not be so large that the output signal from the “earlier” output is already past the next transition after the transition that times the change. At least if a larger change is necessary, the address controller 228 realizes the change in a number of smaller steps (of course smaller steps may also be used when a small change is required).

The size of the steps depends on the duty cycle of the signal that is delayed. If that duty cycle is 50%, the steps should not exceed half a period. This may be realized by maximizing the steps to half a period and adding additional steps until the desired delay has been realized. Alternatively, the delay may be realized by steps of half the required delay (alternately rounded up and down).

If the duty cycle is higher, so that the signal stays longer at the level after the change, the steps may be correspondingly longer. Similarly, a lower duty cycle results in smaller steps. Preferably a higher duty cycle than 50% is used to reduce the need for multiple steps. When the duty cycle differs from 100% by less than the phase resolution of the delay locked loop, a single step always suffices.

If the selection changes to a “later” output of the multiplexer 226 (i.e. an output which outputs a signal that is more delayed than the signal of the previously selected output), the signal from that later output should not be passed to the output of the delay circuit 22 until the relevant transition has reached that “later” output. In the intervening time, the address controller 228 keeps the signal at the output of the delay circuit 22 constant.

The address controller 228 may be realized in any known way to compute from a sequence of desired delays a sequence of selection addresses for the multiplexer for successive output transitions of the delay circuit 22 that meets the conditions outline above.

The function of the frequency dividers 14, 24, 282 can be implemented in various ways. In one embodiment they can be implemented as counters, which count pulses received from the VCO 10, 20 (if appropriate via prescaler 21) and generate an output signal once a number of pulses equal to the desired frequency division ratio has been counted. In another embodiment, they can be implemented as accumulator-adder circuits.

FIG. 3 shows an accumulator adder circuit. The circuit contains an increment register 30, a decrement register 31, a multiplexer 32, and adder 34 and an accumulator register 36. The increment and decrement registers 30, 31 are coupled to a first input of the adder 34 via multiplexer. An overflow output of the accumulator 36 is coupled to the multiplexer to select which of the contents of increment or decrement register 30, 31 is fed to the first input of the adder 34. The output of the adder 34 is coupled to the accumulator 36 and an output of the accumulator is coupled to a second input of the adder 34. The accumulator 36 is clocked by an input signal and the overflow output of the accumulator 36 carries the frequency divided output signal of the circuit.

In operation, adder 34 adds the content P of increment register 30 to the content A of accumulator 36 until an overflow of accumulator 36 is detected (i.e. when A is greater than some value Q). In that case the content (P-Q) of decrement register 31 is used to decrement the content of accumulator 36. Thus, the signal at the overflow output of accumulator 36 will on average have a frequency equal to the frequency at its input divided by X=Q/P. The content A0 of the accumulator 36 after decrementing is a measure of the desired delay to be provided by the delay circuit 12, 22, because A0/P represents the fraction of the period of the input signal that the overflow output is too late, which should be compensated by a delay from delay circuit 12 or 22. To do so the desired delay may be set to (P-1-A0) for the pulse that causes decrementing of the accumulator in frequency divider 24.

With a divider of this type it is not necessary to adjust the frequency division ratio of frequency divider 14, 24 explicitly for individual periods of the frequency divided signal. The number of periods of the VCO signal that fit into one period of the frequency of the divided signal will vary automatically so that the average division ratio is Q/P. When the circuit of FIG. 3 is used as divider 24, 282 this content A may be fed to the delay circuit 12, 22 to control the delay, for example using address controller 228. This obviates the need to compute the desired delay.

1. Electronic device with a frequency synthesizer circuit, the frequency synthesizer circuit comprising
a controllable oscillator;
a frequency divider with an input coupled to the controllable oscillator for receiving an input signal of a first frequency and outputting an output signal of a second frequency, which has an integer division ratio to the first frequency, successive values of the integer division ratios being controlled so that the integer division ratios on average substantially equal a nominal division ratio;
a reference input for receiving a reference signal;
a loop circuit for controlling the controllable oscillator so that the second frequency, on average substantially equals a frequency of the reference signal;
a variable delay circuit coupled between the controllable oscillator and the input of the frequency divider,
a control circuit setting successive delays of the delay circuit so that the delays compensate deviations between period lengths of the output signal of the second frequency and period lengths of a notional signal with a third frequency equal to the first frequency divided by the nominal division ratio.

2. Electronic circuit according to claim 1, wherein the variable delay circuit contains
a delay locked loop circuit comprising a cascade of adjustable delay stages and a loop for adjusting the delays of the delay stages to an integer fraction of a period of a signal deriving from the controllable oscillator,
a multiplexer for tapping an input signal for the frequency divider from a selectable point in the cascade to select the delays.

3. Electronic circuit according to claim 1 wherein the control circuit is arranged to trigger changes in the delays with an output signal of the delay circuit.

4. Electronic circuit according to claim 3, wherein the control circuit is arranged to effect a decrease from at least one the delays to a next delay in more than one step during a period of the output signal of the frequency divider, each step being less than a duration of a level of said output signal that occurs after a transition that triggers the decrease.
